(19) United States
(12) Patent Application Publication
(10) Pub. No.: US 2025/0285697 A1
(43) Pub. Date: Sep. 11, 2025

(54) SPINTRONIC ADAPTIVE APPROXIMATE MEMORY (SAAM)

(71) Applicant: The George Washington University, Washington, DC (US)

(72) Inventors: Abdolah Amirany, Washington, DC (US); Tarek El-Ghazawi, Vienna, VA (US); Hamidreza Imani Porshokouh, Washington, DC (US)

(21) Appl. No.: 19/072,757

(22) Filed: Mar. 6, 2025

Related U.S. Application Data
(60) Provisional application No. 63/562,083, filed on Mar. 6, 2024.

(51) Int. Cl. G11C 27/00

(52) U.S. Cl. CPC G11C 27/005

(57) ABSTRACT

A spintronic adaptive approximate memory (SAAM) is used with or in a neural network. A methodology adaptive approximation is used based on the stochastic behavior of magnetic tunnel junctions (MTJ). The SAAM offers an innovative solution for storing neural network weights with input data-dependent controlled accuracy. The memory significantly reduces power consumption and area overhead while minimizing the loss of accuracy. Key features include bitwise control over memory accuracy, an approximation-aware learning algorithm, and an adaptive write circuit which broadens applications of the designed approximate memory, beyond neural network hardware accelerators. The disclosure evaluates SAAM's performance through functional simulations, statistical analyses, and neural network implementations, demonstrating its advantages over existing approximate memories. These simulations demonstrate power efficiency improvements ranging from 10% to 40%. This enhancement is achieved at the cost of a negligible accuracy reduction, ranging from 1% to 7%.

### RELATED APPLICATIONS

This application claims the benefit of U.S. Provisional Application No. 63/562,083, filed Mar. 6, 2024, the entire contents of which are incorporated herein by reference. The references cited in the provisional application are hereby incorporated by reference in their entireties herein.

### BACKGROUND OF THE DISCLOSURE

### Background of the Related Art

Neural networks (NN), which constitute the backbone of many artificial intelligence (AI) applications, heavily rely on the storage and precision of their weight parameters [1, 2]. The weight number problem of AI emerges with increasing attention towards hardware implementation of AI [3, 4]. In many AI hardware accelerators with limited resources, such as embedded systems and edge devices, the challenge of representing and storing these weights becomes more and more important [5].

There are different ways to address the weight number issue and the associated challenges. These solutions include, but are not limited to, quantized NN (QNN) [4] and approximate NN (ANN) [6]. Approximation can be introduced at different stages of an NN, one of which is the weights memory. Approximate memory can be employed for storing NN weights, with the goal of reducing area and power consumption. Quantization is also a very effective method to reduce the number of bits required for weight storage. At the same time quantization also reduce power consumption and area overhead [3, 7]. Despite this advantage quantization may suffer from high network accuracy drop which limit its application in accuracy sensitive applications.

The approximate memories don't offer the fascinating power and area efficiency of QNNs, but they don't suffer from high accuracy drop of QNNs. There are many ways for hardware implementation of approximate memories. In the Complementary Metal-Oxide Semiconductor (CMOS) world, the two widely used of these ways are: low supply voltage static random access memory (SRAM) [8] and low refresh rate dynamic random access memory (DRAM) [9]. Considering that these two methods only control the frequency of DRAM and supply voltage of SRAM, these methods do not reduce the area, but they do reduce the power consumption. Another major drawback of the two mentioned methods is that these two methods affect the entire memory because it is not possible to control the supply voltage or the frequency of a part of the memory separately or it is very difficult. This issue results in a trade-off: to achieve significant power reduction using these methods, we must substantially reduce the supply voltage or frequency, leading to a notable drop in NN accuracy. Conversely, maintaining accuracy results in only a marginal reduction in power consumption.

One of the technologies that can address the aforementioned issues and also bring some other fascinating advantage is spintronic. These advantages are compatible with CMOS transistors, high endurance, and most importantly nonvolatility [10]. Thanks to these advantages spintronics can have promising applications in data storage, sensors, and computing. It has the potential to create more energy-efficient and faster electronic devices while also enabling new paradigms in computing and information processing [11]. Magnetic tunnel junction (MTJ), as the basic element of the spintronic circuit, also has a very special property that can be useful in approximate computing and approximate memory implementation [12]. This feature is the stochastic behavior of MTJ in the current below the critical current [13].

### SUMMARY OF THE DISCLOSURE

Using the stochastic behavior of the MTJ in the current below the critical current, a new kind of the approximate memory is provided in this disclosure that can be used in hardware implementation of a NN. In the memory, the accuracy control factor is the MTJ switching current, and this factor can easily be controlled by the size of the transistors, the method can apply different approximations to the bits with different values. This feature allows the memory to reduce the power consumption without significant loss of accuracy.

Also, the method reduces area which was not possible in low supply voltage SRAM and low refresh rate DRAM. Also, to further investigate the effectiveness of the method, this method was applied both on the network with signed and unsigned weights using an 8-bits memory structure. Also, to improve the accuracy drop in this paper, two other methods are also provided. In the approximation-aware learning, the effect of approximation is introduced in the learning algorithm, which significantly improves the accuracy without imposing any hardware overhead. Also, a control circuit has been added to the memory, which determines the accuracy based on the input values. This adaptive method makes it possible to use the memory in other applications such as image processing in addition to the hardware implementation of neural networks.

We now review the spintronic technology, stochastic behavior of the MTJ and previous CMOS and spintronic approximate memories.

### MTJ and Its Stochastic Behavior

The Magnetic Tunnel Junction (MTJ) is the fundamental component of a spintronic circuit. As shown in FIGS. 1A, 1B, the MTJ is a sandwich-like structure device with two ferromagnetic layers separated by a thin insulating barrier. The MTJ operates based on a quantum phenomena called tunneling magnetoresistance (TMR). Based on this phenomena, resistance of the junction varies based on the relative alignment of the magnetic moments in the ferromagnetic layers [13]. When these moments are parallel (P), electrons can easily tunnel through, resulting in a low-resistance state. Conversely, when the moments are antiparallel (AP), tunneling becomes less likely, leading to a high-resistance state. This property is used in various applications, including magnetoresistive sensors for detecting magnetic fields and magnetoresistive RAM (MRAM). MTJ as nonvolatile memory technology also known for its speed, low power consumption, and high endurance [13].

A key parameter in the MTJ device is the critical current. The critical current in an MTJ is the minimum electrical current density necessary to induce a deterministic and controlled switching of the magnetic orientation of one of its ferromagnetic layers [13]. This parameter plays a vital role in the operation of the MTJ, particularly in applications like MRAM, where low-power, fast, and reliable switching of data bits is essential. Equation (1) shows the switching probability of the MTJ in current below the critical currents [13].

$$P ( I , t ) = 1 - exp \{ - \frac{t}{{T}_{0}} exp [ - {Δ ( 1 - \frac{I}{{I}_{cri}} )}^{2} ] \} \qquad ( 1 )$$

In Eq (1), t is the width of the applied current pulse, T₀ is the attempt time, Δ is the thermal stability factor, I is the current magnitude pass through MTJ, and I_{cri} is the critical current [14]. FIG. 2 shows the MTJ switching probability for different current pulse duration [13].

The stochasticity feature (of switching in MTJ memory cells when using currents below the critical current) has many applications such as true random number generation [15, 16] and stochastic computing [5, 17]. This feature can be employed in the design of approximate memory.

### CMOS Approximate Memory Implementation

In the CMOS world, there are two kinds of approximate memory, low supply voltage SRAM [8] and low refresh rate DRAM [9]. In conventional SRAM, the cells are designed to operate at a specific supply voltage level, which ensures stable and accurate read and write operations. However, in low supply voltage SRAM, the supply voltage is intentionally reduced to a level below the nominal voltage. This lower voltage reduces the energy consumed by each memory cell during operations. This voltage reduction can introduce three different kinds of errors: read error, write error and bit flipping.

Supply voltage reduction offers fascinating energy savings since power consumption is quadratically related to supply voltage. However, this method has two drawbacks [8]. First, the precise control of the supply voltage for different parts of the circuit is challenging and can lead to wiring and routing complexity. Second, in this method, we lack bit-level control over the supply voltage of memory and can only reduce the entire memory cell's supply voltage, which can introduce errors in the most significant bits (MSB). Errors in MSBs result in a significant loss of accuracy in neural networks.

In typical DRAM, a refresh operation occurs at a high rate to prevent data loss due to charge leakage. This refresh operation consumes a non-negligible amount of power [9]. Low refresh rate DRAM, as its name suggests, reduces the frequency of these refresh operations. This reduction in the refresh rate results in lower power consumption compared to traditional DRAM but can cause data loss [9].

Both low supply voltage SRAM and the low refresh rate DRAM methods lack bit-level control. Regarding low refresh rate DRAM, it can be said that this method is more practical from a fabrication and implementation point of view. The low refresh rate DRAM also doesn't impose wiring and routing complexity, but this method is less power-efficient because power is quadratically related to supply voltage, while it is linearly related to frequency.

Also, low refresh rate DRAM method is strongly influenced by fabrication process variation and environmental conditions. These two factors exponentially change the leakage current of the transistors, which are the cause of data loss in DRAM, and as a result, the low refresh rate DRAM error rate is different in different environmental conditions and for even different chips.

### Previous Spintronic Approximate Memories

Prior spintronic approximate memory in Sayed (N. Sayed, R. Bishnoi, and M. B. Tahoori, “Approximate Spintronic Memories,” ACM Journal on Emerging Technologies in Computing Systems, vol. 16, no. 4, pp. 1-22, 2020, doi: 10.1145/3404980) offers significant advantages, especially in its integration for approximate computing. The design in Sayed utilizes the inherent strengths of spintronic technology, like nonvolatility and high density, to enhance energy efficiency and performance in application such as image processing. The design in Sayed is particularly advantageous in applications where slight inaccuracies are permissible, thereby reducing write latency and energy consumption.

Despite the aforementioned benefits, the design in Sayed faces challenges, mainly in balancing error rates with overall system gains and addressing fabrication process variations. These challenges are essential considerations for ensuring the practicality and reliability of approximate memories in real-world applications. Also fixed level of approximation in the design in Sayed impacts its circuit performance and reliability. This fixed approximation approach can lead to challenges in maintaining consistent performance across different applications, potentially affecting the overall effectiveness of the design in Sayed in certain computing applications.

Ranjan (A. Ranjan, S. Venkataramani, X. Fong, K. Roy, and A. Raghunathan, “Approximate storage for energy efficient spintronic memories,” presented at the Proceedings of the 52nd Annual Design Automation Conference, 2015) tries to enhance the energy efficiency of spintronic memories through approximate storage. They identify mechanisms at the bit-level for energy-quality trade-offs and propose a quality-configurable memory array design, which allows data storage with varying accuracy based on application requirements.

As the design in Ranjan pushes for lower energy consumption, it may lead to increased error rates, affecting the reliability of stored data. Additionally, fabrication process variation can significantly impact the performance and consistency of the design in Ranjan. Also the quality-configurable method proposed in Ranjan requires sophisticated control mechanisms to adjust the level of approximation, which will lead to a significant area overhead.

### Quantized Neural Networks (QNN)

QNNs are a type of neural network in which the weights and/or activations of the network are quantized to a lower bit-width representation, typically using fewer bits than the standard 32-bit or 64-bit floating-point format [4]. This quantization process reduces the computational and memory requirements of the neural network, making it more power-efficient and suitable for deployment on resource-constrained devices. However, QNNs also come with some drawbacks. Most importance of these drawbacks is loss of model accuracy, training challenges, and sensitivity to weight initialization.

One of the primary drawbacks of quantization is that reducing the bit-width of weights and activations can lead to a loss of model accuracy [4]. More aggressive quantization, such as reducing weights to very low bit-widths like binary and ternary, can result in significant degradation in performance [20].

QNNs also often require specialized training techniques. Training models with lower bit-width representations can be less stable and may require additional techniques like quantization-aware training to achieve reasonable accuracy [7]. At the same time QNNs can be sensitive to weight initialization, making it crucial to find suitable initialization schemes to achieve good convergence during training [20].

### SAAM Memory

A spintronic adaptive approximate memory (SAAM) is provided for hardware implementation of a neural network. A methodology adaptive approximation is used based on the stochastic behavior of magnetic tunnel junctions (MTJ). The SAAM offers an innovative solution for storing neural network weights with input data-dependent controlled accuracy. The memory significantly reduces power consumption and area overhead while minimizing the loss of accuracy. Key features include bitwise control over memory accuracy, an approximation-aware learning algorithm, and an adaptive write circuit which broadens applications of the designed approximate memory, beyond neural network hardware accelerators. The disclosure evaluates SAAM's performance through functional simulations, statistical analyses, and neural network implementations, demonstrating its advantages over existing approximate memories. These simulations demonstrate power efficiency improvements ranging from 10% to 40%. This enhancement is achieved at the cost of a negligible accuracy reduction, ranging from 1% to 7%.

These and other objects of the disclosure, as well as many of the intended advantages thereof, will become more readily apparent when reference is made to the following description, taken in conjunction with the accompanying drawings.

### BRIEF DESCRIPTION OF THE FIGURES

The accompanying drawings are incorporated in and constitute a part of this specification. It is to be understood that the drawings illustrate only some examples of the disclosure and other examples or combinations of various examples that are not specifically illustrated in the figures may still fall within the scope of this disclosure. Examples will now be described with additional detail through the use of the drawings, in which:

FIG. 1A shows an MTJ Structure [13] in accordance with a non-limiting example illustrative embodiment of the disclosure.

FIG. 1B shows an MTJ write circuit.

FIG. 2 shows an MTJ switching probability for different current pulse duration. Transistors that cannot provide the sufficient current for achieving 100% switching probability are considered small.

FIG. 3 is a spintronic approximate memory (SAM) circuit. P5 and P6 transistors are small transistors which provide lower energy consumption but are not guaranteed to perform the write operation properly.

FIG. 4 is a spintronic adaptive approximate memory (SAAM) circuit. P9 and P10 transistors are added in parallel to P5 and P6 respectively. The parallel transistors are able to provide 100% switching probability since the sum of their write current is greater than Icri. These two extra transistors will operate based on different conditions of the write data or quality of the application execution feedback (Iₙ₊₁).

FIG. 5 is a block diagram of a 2^{m}×8 bits spintronic approximate memory array.

FIG. 6 is a chart showing accuracy vs. power saving vs area saving for MLP using unsigned weight.

FIG. 7 is a chart showing accuracy vs power saving vs area saving for LeNet-5 using unsigned weight.

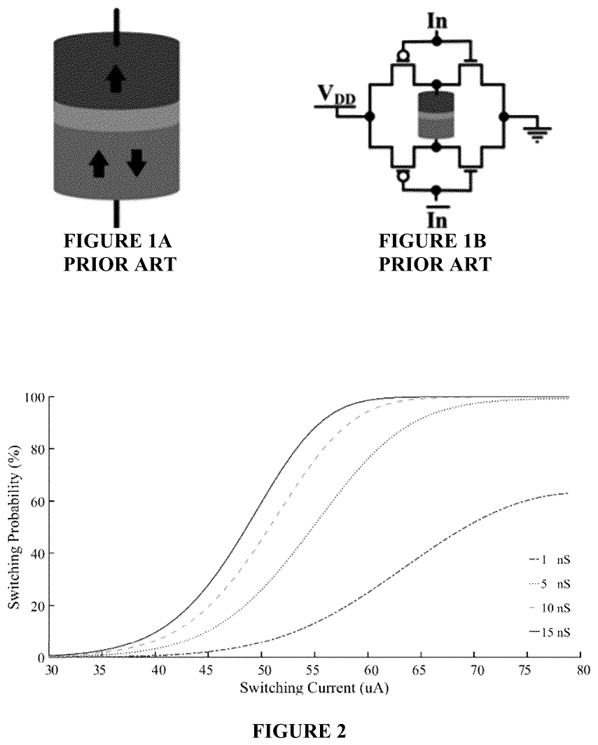

### DETAILED DESCRIPTION OF THE PREFERRED EMBODIMENTS

In describing the illustrative, non-limiting preferred embodiments of the invention illustrated in the drawings, specific terminology will be resorted to for the sake of clarity. However, the invention is not intended to be limited to the specific terms so selected, and it is to be understood that each specific term includes all technical equivalents that operate in similar manner to accomplish a similar purpose. Several embodiments of the invention are described for illustrative purposes, it being understood that the invention may be embodied in other forms not specifically shown in the drawings.

We first explain the details and operation principal of one non-limiting example embodiment of the spintronic approximate memory cell. After that the approximation-aware training method is also explained. In one embodiment, the spintronic approximate memory is an adaptive write circuit. Finally, using the designed spintronic approximate memory cells we provide an 8-bits memory array.

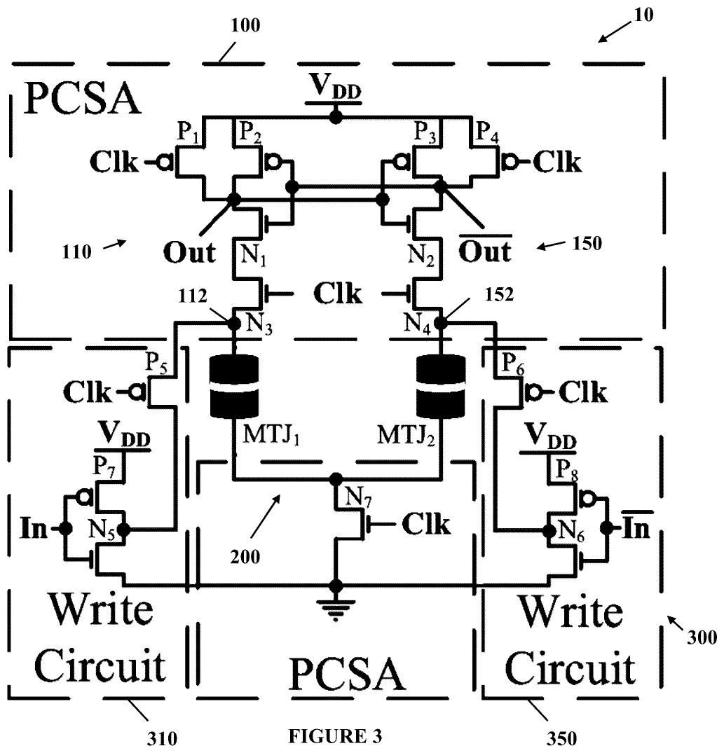

### Spintronic Approximate Memory (SAM) 10 (FIG. 3)

FIG. 3 shows the circuit schematic of the spintronic approximate memory (SAM) 10. As shown, the memory circuit 10 has three parts: PreCharge Sense Amplifier (PCSA) 100, MTJ tree 200, and write circuit 300.

The PCSA 100 has a first PCSA or read circuit branch 110 and a second PCSA or read circuit branch 150. Any suitable read circuit can be utilized. [21] The first read circuit branch 110 has two transistors P₁/P₂ connected in parallel and two transistors N₁/N₃ connected in series. The two transistors P₁/P₂ form a first read circuit parallel transistor pair P₁/P₂, and the two transistors N₁/N₃ form a first read circuit series pair. The first series transistor pair N₁/N₃ are connected in series with the first parallel transistor pair P₁/P₂.

The second read branch 150 has two transistors P₃/P₄ connected in parallel and two transistors N₂/N₄ connected in series. The two transistors P₃/P₄ forma second parallel read circuit transistor pair P₃/P₄, and the two transistors N₂, N₄ form a second series read circuit pair. The second series transistor pair N₂/N₄ are connected in series with the second parallel transistor pair P₃/P₄.

The first parallel transistor P₁, P₄ of each of the first and second parallel transistor pairs receives at its Gate a Clk input, and the other transistor P₂, P₃ of each pair receives at its Gate the output, Out and O̅u̅t̅, from the other parallel transistor pair. Thus, at the first and second read circuit branches 110, 150, each of the first and second parallel transistor pairs P₁/P₂ and P₃/P₄ is connected in series with a respective one of the first and second series transistor pairs N₁/N₃ and N₂/N₄. The first series transistor N₁/N₂ of each of the series pairs N1/N3 and N2/N4 receives at its Source the output from the respective parallel transistor pair and at its Gate an output from the other parallel transistor pair. The second series transistor N₃/N₄ of each of the first and second series pairs N₁/N₃ and N₂/N₄ receives the Clk signal and at its Source the output from the first series transistor N₁/N₂. The second series transistor N₃/N₄ of each of the first and second series transistor pairs N₁/N₃ and N₂/N₄ has a first read circuit output 112 and a second read circuit output 152, respectively.

These transistors are configured in this way to provide a positive feedback for a read operation. This positive feedback circuit measures the difference of voltage between MTJ1 and MTJ2 and projects that onto Out and O̅u̅t̅. Out and O̅u̅t̅ are the outputs of the read operation. When you read a memory cell you get an output signal, and O̅u̅t̅ is the inverse of Out. The PCSA 100 is the read circuit of the memory cell. The same Clk is used at the Gate for P₁, P₃, P₅, P₆, N₃, N₄, P₅, P₆, and N₇ to synchronize the read operation.

The MTJ tree 200 has a first MTJ1 and a second MTJ2. The first MTJ1 is connected in series to the first branch 110 of the PCSA 100, and the second MTJ2 is connected in series to the second branch 150. The first MTJ₁ has a first MTJ₁ input that is connected to the first read circuit output 112 of the second series transistor N₃ of the first branch 110, and the second MTJ₂ has a second MTJ₂ input that is connected to the second read circuit output 152 of the second series transistor N₄ of the second branch 150. The first and second MTJ₁, MTJ₂ always have a state that is opposite the other. For read operation, the difference of resistance between these two cells is the data that is written in the memory cell. The reason for this differential reading is that resistance of a single MTJ cell cannot determine if the data is 1 or 0. The relative resistance is the stored data. Two MTJs are used to prevent leakage and make the cell error-free. A first MTJ₁ output and second MTJ₂ output are connected to the input Source of a seventh transistor N₇ (which is part of the PCSA 100, which has a Clk input at the Gate. The read circuit should be connected to ground for the read operation and N7 provides that connection.

The Write Circuit 300 has a first write circuit branch 310 and a second write circuit branch 250, which are coupled in series with the first read circuit branch 110 and the second read circuit branch 150 to receive the first read circuit output 112 and the second read circuit output 152, respectively. The first and second write circuits 310, 350 each have a fifth and sixth transistor P₅/P₆ that has a Gate connected to the Clk and an input at the Source connected to the output of the third and fourth transistors N₃, N₄ to receive the first and second read circuit outputs 112, 152, respectively. The first and second write circuits 310, 350 also have a first and second write circuit series transistor pairs P₇/N₅ and P₈/N₆. One transistor P₇, P₈ has VDD at its Source, and the other transistor receives the P₅, P₆ output at its Source. The transistors P₇, N₅ have a Gate input In, and the transistors P₈, N₆ have an inverse Gate input I̅n̅. The output from each write circuit 310, 350 is connected to ground, and to the output from the N7 transistor.

It is noted that the switching current is the current that is applied to the MTJ to change its state. Transistors P₅ and P₉ provide the switching current to the MTJs. It may or may not have large enough value to make the switching. However, the critical current is the point at which applying a current of a smaller value results in stochastic write operations. Transistors with smaller sizes cannot provide enough current to pass the critical value. This results in a stochastic write operation which consumes less power. Reducing the switching current increases the error.

The write circuit transistors (P₅-P₈, and N₅-N₆) are reduced in size by approximately 40% to reduce the MTJ switching current below the critical current. Reducing the MTJ switching current below the critical current, results in a small percentage error in data storage accuracy while saving a significant amount of power. As a result, the probability of MTJ switching is reduced for example by say 10%. In practical terms, this means that the stored data is correct 90% of the time. That is, the present device 10 reduces the transistor size which saves power but also results in a current that is below the MTJ critical current, which in turn reduces the probability that switching of the MTJ will occur (i.e., subcritical switching or switching that occurs below the critical current). The error probability is shown in FIG. 2, where the error probability is 100% switching probability. However, that switching accuracy may be acceptable for certain data, e.g., of lower impact or importance.

At first glance, a 40% reduction in the size of the 6 transistors might not seem to offer a significant area reduction. However, it's crucial to note that write circuit transistors are typically quite large, often five times of the size of minimum-size transistors [2]. Considering this, reducing the size of these transistors by 40% is roughly equivalent to removing 12 minimum-size transistors from the circuit. Excluding the write circuit, a spintronic memory circuit only has 9 minimum-size transistors.

Like conventional PCSA-based memory, the operation of the memory can be divided into two following phases, namely a Precharge Phase (i.e., write operation) and an Evaluation Phase (i.e., read operation).

The Precharge Phase performs the write operation. Here, the Clk is at its low level, so that the PMOSs P₁ and P₄ turn ON and precharge Out and O̅u̅t̅ to the Voltage Source, VDD. At the same, time P₅ and P₆ turn ON, which connects MTJ₁ and MTJ₂ to the write circuit 200 for write operation. Transistors N3/N4 are precharged to VDD to provide the voltage for the write operation. Since the write operation intends to change the state of the saved data (MTJs), MTJs should be connected.

During the Evaluation Phase (also known as the read phase or read operation), the Clk is high, which disconnects the write circuit from the MTJs. The write circuit 300 is disconnected to prevent change of value stored in MTJ₁, MTJ₂. At the same time, N₃ and N₄ turn ON and connect the MTJs to the PCSA 100. During this phase, the MTJ with lower resistance (parallel state) discharge its corresponding output faster and the other output becomes V_{DD}.

In is the input data that we want to store in our memory cell and I̅n̅ is its inverse. Since the write circuit has a transistor that cannot provide the critical current, the write operation is not guaranteed to succeed. Therefore, it is approximate. The input data (In) and its inverse I̅n̅ will be stored in the memory cells (MTJs).

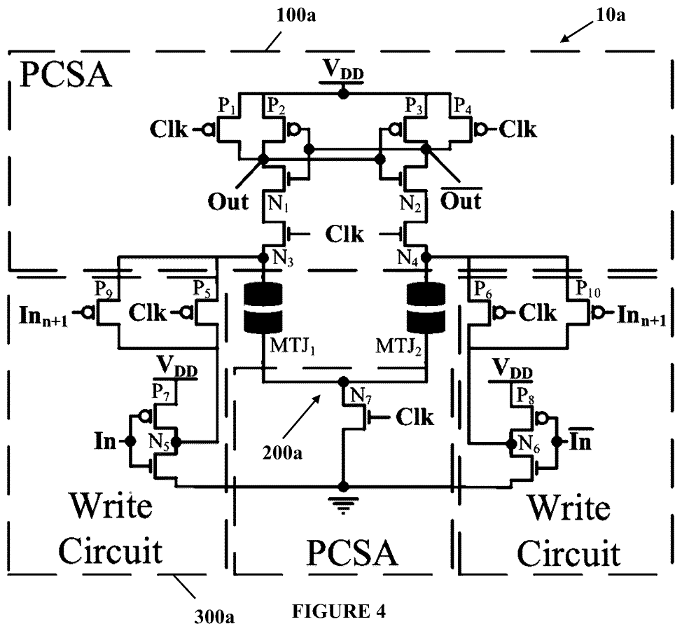

The SAAM 10 offers an innovative solution for storing neural network weights with input data-dependent controlled accuracy. In the memory, the accuracy control factor is the MTJ switching current, and this factor can easily be controlled by the size of the transistors, the method can apply different approximations to the bits with different values. Weights are the input data to our memory cell. The SAAM changes the stochasticity of the write operation based on input data or application feedback by using two parallel transistors in the write circuit (P5+P9 and P6+P10 in FIG. 4). If the input data is small, both transistors (P5+P9 and P6+P10 in FIG. 4) will be used for providing the switching current. This results in no stochasticity in write operation and higher power consumption. However, if the input data is bigger than a certain amount, only one transistor (P5 and P6 in FIG. 4) will be used for the write operation which makes the write operation approximate but results in less power consumption. Two transistors act as one big transistor which can provide a current more than the critical current. A single transistor (small) provides a switching current less than the critical current.

### Approximation-Aware Training Method

To prevent the loss of accuracy in applications such as neural networks, learning algorithms can be modified in such a way that the approximation in these algorithms is modeled. For this purpose, the following steps can be taken after each epoch: (1) Extracting the weight matrix. (2) Adding errors to the least significant bits according to the structure and MTJ switching probability. (3) Using the new weight matrix in the next epoch.

By performing the above steps, the effect of approximation is included in each epoch and as a result, higher accuracy can be achieved. It is also noteworthy that this method is independent of the type of learning algorithm used and can be used for different learning algorithms. Also, this method is only used in the learning phase, and as a result, it does not impose any hardware overhead.

### Spintronic Adaptive Approximate Memory Cell (SAAM) 10a (FIG. 4)

Turning to FIG. 4, a spintronic adaptive approximate memory (SAAM) 10a is shown in accordance with another non-limiting illustrative embodiment of the present disclosure. Without intending to be limiting to any embodiment, the terms and components (e.g., parts, elements, features, processes) used in the current embodiment are consistent with, and have the same purpose, function, and advantages as, those described in the earlier embodiment of FIG. 3, including but not limited to the PCSA 100a, Write Circuit 300a, and MTJ circuit 200a. These benefits include, but are not limited to, improved efficiency, smaller space, and less energy consumption. To avoid unnecessary repetition, these terms and components are not repeated herein. Any reference to specific terms or components should be understood to have the same meaning, purpose, function, and advantage as previously shown and described. Differences are described here, but there may be other variations that are not explicitly detailed.

FIG. 4 shows the circuit schematic of the spintronic adaptive approximate memory 10a. The SAAM memory 10a is the same as the SAM memory 10 of FIG. 3, except that in this circuit two transistors (P₉ and P₁₀) are added. The transistors P₉/P₁₀ are part of the write circuit. There are two possible cases. They can both conduct and work in parallel to have accurate write operations. However, in the other case when only one of them is running the current will be lower than the critical current and therefore the write operation will be approximate. Moreover, they are parallel because they can increase the current flow from N₃ to N₅ or N₄ to N₆ in FIG. 4. These two transistors control the MTJ write current based on the input of the next significant bit (Inₙ₊₁). When the next significant bit In₍ₙ₊₁₎ is zero, these two transistors turn ON and higher current pass through the MTJs results in higher write probability.

Due to the need for control circuits, this method causes a slight increase in the hardware overhead of the memory, but it has more applications compared to the approximation-aware training method described herein and is not only limited to the hardware implementation of neural networks. Also, this method can be used in combination with the approximate memory cell. The SAAM memory 10a (FIG. 4) is less power-efficient than the SAM (FIG. 3) because it has the feature of adaptability added. It is adaptive because it can choose to use both parallel transistors to make a big transistor or use a single small transistor based on the input data. Of course, other configurations can be provided to make the system adaptive. The transistors can also be the same size or different sizes with one transistor being larger than the other transistor. The larger the transistor, the larger the current that can be provided to the MTJ. In the current embodiment, the big transistor (e.g., combined P₅ and P₉) provides a current above the critical current, and the small transistor (e.g., P₅ or P₉) provides sub-critical level current.

It is noted that the memory is spintronic to utilize the stochastic switching behavior of MTJs, which are spintronic memory cells. In addition, the write circuit can compare input data with stored data to avoid writing duplicate. This can be accomplished using a comparator circuit to compare the input data against the data already saved in the cell.

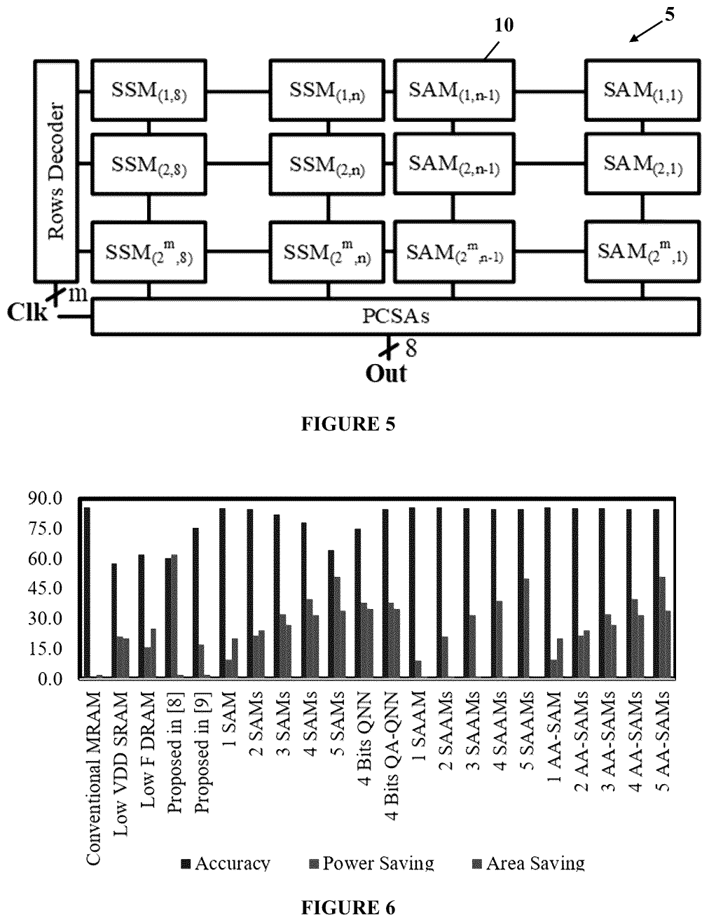

### 8-Bits Memory Array (FIG. 5)

FIG. 5 shows 8-bit memory array 5 in accordance with an illustrative non-limiting embodiment of the disclosure. Unlike low supply voltage SRAM and low refresh rate DRAM, in the design we have bitwise control of the memory accuracy. Using this advantage, the memory array shown in FIG. 5 is designed. In this memory array, we used spintronic approximate memory (SAM) cell 10 with reduced write circuit transistors size for least significant bits (LSB) and standard spintronic memory (SSM) cell for MSBs.

FIGS. 3, 4 are memory cells used for storing a single bit. In FIG. 5, Standard Spintronic Memory (SSM) cells do not have stochastic behavior and are not approximate. SSMs are used for most significant bits and SAM 10 or SAAM are used for least significant bits. By this, we can minimize the error rate of an approximate memory. For example, if we want to store a 16-bit number, the bits 16 to 9 (MSBs) are stored in SSMs and bits 8 to 1 (LSBs) are stored in approximate cells (SAM or SAAM). FIG. 5 shows a memory which has arrays of SSMs and SAMs.

In the 8-bits approximate memory array, n can be any number between 0 and 8. Having more Spintronic Approximate Memories (SAMs) results in lower area and improved energy savings but at the expense of accuracy. Also, in the architecture shown in FIG. 5, SAAM 10a can be used instead of SAMs 10 to increase accuracy. Another way to increase accuracy is to use SAM in LSBs, use SAAM in middle bits and use accurate memory cells in MSBs.

Adjustable refers to deciding the number of exact memory compared to the number of SAAMs (approximate cells) in a given array. Adaptable refers to automatic adaptability of stochasticity of a memory cell based on the input value or the application feedback.

### Results and Discussion

In this section, we first evaluate the functional performance of the SAM, followed by an assessment of its statistical performance. The statistical simulation takes into account fabrication process variations for realism. Finally, we explore the performance of the memory in implementing various NNs and compare it with other approximate memories.

### Functional Simulations

Using MTJ model in Wang (Y. Wang, Y. Zhang, E. Y. Deng, J. O. Klein, L. A. B. Naviner, and W. S. Zhao, “Compact model of magnetic tunnel junction with stochastic spin transfer torque switching for reliability analyses,” Microelectronics Reliability, vol. 54, no. 9-10, pp. 1774-1778, 2014, doi: 10.1016/j.microrel.2014.07.019) and 40 nm CMOS technology, the circuit simulated using HSPICE tool. Table I shows the parameters of the CMOS transistors and the MTJ devices and their variations. Table II shows the performance of the spintronic approximate memory cell compared to the conventional PCSA-based spintronic memory. In this table equivalent unit size transistor (UST) metric used for area comparison.

As Table II shows the spintronic approximate memory offers 30% lower area and consumes 22% and 32% average and static power respectively. In term of write delay the circuit is 4% slower than conventional PCSA-based spintronic memory but as clock period is 5 ns, the write delay of 4.9 ns is still acceptable. Considering read delay, as the write transistor size reduction reduces the internal nodes capacitance, the spintronic approximate memory offers 3% lower read delay.

### Statistical Analyses

For statistical analyses, first we simulate our design in the presence of the fabrication process variation using Monte-Carlo simulation. In the Monte-Carlo simulation the critical parameter of the circuit chosen using a Gaussian distribution with sigma value provided in Table I.

TABLE 1
Parameters of the CMOS Transistors and
the MTJ Devices and Their Variations

| | | | | | ±3σ |
|---|---|---|---|---|---|
| Parameter | | | Value | | Variation |
| MTJ | Shape | | Round | | |
| | MTJ diameter | | 40 | nm | 7.2% |
| | Barrier thickness | | 0.9 | nm | 5% |
| | Resistance area product | | 10Ω · μm² | | 15% |
| | Free layer thickness | | 0.9 | nm | 5% |
| | TMR under zero bias | | 200% | | 10% |
| | voltage (TMR₀) | | | | |
| | MTJ resistance | | 10~30 | kΩ | — |
| | Switching time | | ~5 | ns | — |
| Transistors | Gate length | | 40 | nm | 5% |
| | Gate | Minimum size | 40 | nm | |
| | width | Conventional | 200 | nm | 10% |
| | | write circuit | | | |
| | | Approximate | 120 | nm | |
| | | write circuit | | | |

| | | | | |
|---|---|---|---|---|
| Setup | Supply voltage | 1.0 | V | 10% |
| | Temperature | 300 | K | 270 K to 360 K |
| | Simulation step | 10 | ps | — |
| | Clock frequency | 100 | MHz | — |

TABLE II
Performance of the Approximate Memory

| | | | PCSA-based | Spintronic |
|---|---|---|---|---|
| | | | spintronic memory | approximate |
| Implementation | | | [21] | memory |
| Power | Average | (μW) | 24.5 | 19.1 |
| | Write | (μW) | 19.8 | 15.9 |
| | Static | (nW) | 987 | 674 |
| Delay | Read | (pS) | 251 | 243 |
| | Write | (nS) | 4.7 | 4.9 (for |
| | | | | successful write) |

| | | |
|---|---|---|
| UST | 39 | 27 |

TABLE III
Statistical Analyses of the 8-Bits
Approximate Spintronic Memory Array

| Implementation | | ER | MED | NMED | MRED | NoEB |
|---|---|---|---|---|---|---|
| Low V_{dd} SRAM [8] | | 95 | 255 | 7.5 | 52 | 2.9 |
| Low f DRAM [9] | | 91 | 255 | 6.3 | 48 | 3.4 |
| Proposed in [18] | | 98 | 255 | 6.7 | 67 | 2.6 |
| Proposed in [19] | | 92 | 255 | 4.6 | 51 | 2.9 |
| Spintronic | 1-bit | 73 | 1 | 0.74 | 4.0 | 7.1 |
| approximate memory | 2-bits | 84 | 3 | 0.81 | 5.9 | 6.2 |
| | 3-bits | 91 | 7 | 0.98 | 7.1 | 5.2 |
| | 4-bits | 94 | 15 | 1.01 | 10.1 | 4.5 |
| | 5-bits | 97 | 31 | 2.91 | 21.5 | 3.8 |
| Spintronic adaptive | 1-bit | 68 | 1 | 0.64 | 3.1 | 7.9 |
| approximate memory | 2-bits | 81 | 3 | 0.76 | 5.2 | 7.1 |
| | 3-bits | 90 | 7 | 0.91 | 6.7 | 6.9 |
| | 4-bits | 92 | 15 | 0.98 | 9.1 | 6.7 |
| | 5-bits | 94 | 31 | 1.41 | 14.3 | 6.1 |

Table III shows the results of the statistical analyses including error rate (ER), maximum error distance (MED), normalized mean error distance (NMED), mean relative error distance (MRED), and the number of effective bits (NoEB) [22]. The NoEB metric provides an indication of the number of bits in the output that are free from errors [23]. It serves as a measure of the accuracy and reliability of the output in terms of bit correctness.

Table III indicates that low supply voltage SRAM and low refresh rate DRAM exhibit high MED, NMED, and MRED values. This is primarily due to their lack of bitwise control, which also resulting in low NoEB. In contrast, the design, thanks to its bitwise control, offers significantly improved accuracy metrics. It's important to note that the results in Table III are based on Monte-Carlo simulations, which simulate real-world scenarios. Also, as Table III indicates using SAAM significantly improves accuracy metric which confirms the motivation behind its design. The present device provides a tradeoff between accuracy and power consumption a variety of configurations can be chosen. The exact size of transistor widths is different from a fabrication foundry to another one.

### Neural Network Implementation

To comprehensively assess the performance of the design in neural network implementation, we utilized it to store the weights of two distinct networks: LeNet-5 [24] and a multilayer perceptron (MLP). These networks were trained using MNIST and FMNIST datasets. Furthermore, to ensure a fair and informative comparison, we implemented all networks using both signed and unsigned weight representations.

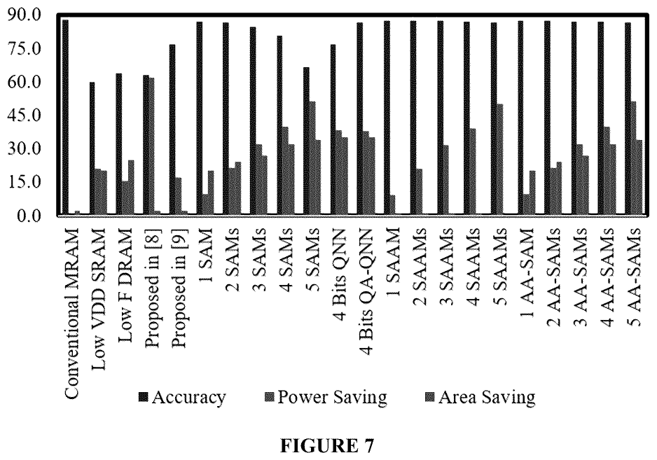

It is noteworthy that except for 4 bits QNN, all the implementations were done in the same conditions and only the memory used to store the weights was different. FIGS. 6-7 show the accuracy vs power saving vs area saving for different networks for both signed and unsigned weight representation.

As depicted in FIGS. 6 and 7, employing 2 SAMs yields accuracy nearly equivalent to that of an accurate implementation. For energy-constrained applications, 3 or even 4 approximate bits can be employed. With 3 or 4 approximate bits, up to 40% power efficiency is achievable at the expense of only 5% to 10% drop in accuracy. It's worth noting that the power efficiency of 4 approximate bits matches that of a 4 bits QNN while still maintaining higher accuracy than a 4 bits QNN.

Also, as FIGS. 6 and 7 show using even 5 SAAMs or SAM with approximation-aware learning offer the same accuracy as accurate memory, which highlighted the advantage of these two designs. According to these facts, SAM can be used with the approximation-aware learning method for applications that only aim the hardware implementation of neural networks. For more general applications, SAAM can also be used, which, in addition to acceptable accuracy, consumes up to 50% less power.

Compared to low supply voltage SRAM and low refresh rate DRAM the implementation based on the memory by far surpasses them both in power saving and accuracy. The reason for this because of lack of bitwise accuracy control in those methods as explained.

### CONCLUSION

The SAAM 10a represents a significant advancement in approximate memory technology, offering a balance between power efficiency, area savings, and accuracy. Its innovative use of spintronics technologies and adaptive approximation techniques enables more efficient neural network implementations, particularly on power-constrained devices. Statistical simulations confirm SAAM's superiority over conventional methods in terms of error rates and effectiveness. The application of SAAM in neural networks, investigated by implementing LeNet-5 and MLP, shows promising results with minimal accuracy loss, highlighting its potential usage in AI and edge computing applications. The neural network implementation result based on the SAM and SAAM and also approximation-aware learning algorithm, demonstrates a up to 40% reduction in power consumption and 25% lower area overhead compared to traditional methods. Additionally, the adaptability in SAAM ensures a negligible accuracy loss of less than 3%.

The following references are hereby incorporated by reference in their entireties. [1]P. Yao et al., “Fully hardware-implemented memristor convolutional neural network,” Nature, vol. 577, no. 7792, pp. 641-646, January 2020, doi: 10.1038/s41586-020-1942-4. [2]A. Amirany, K. Jafari, and M. H. Moaiyeri, “DDR-MRAM: Double Data Rate Magnetic RAM for Efficient Artificial Intelligence and Cache Applications,” IEEE Transactions on Magnetics, pp. 1-1, 2022, doi: 10.1109/tmag.2022.3162030. [3]P. Rzeszut, J. Checinski, I. Brzozowski, S. Zietek, W. Skowronski, and T. Stobiecki, “Multi-state MRAM cells for hardware neuromorphic computing,” Sci Rep, vol. 12, no. 1, p. 7178, May 3, 2022, doi: 10.1038/s41598-022-11199-4. [4] Z. Yang et al., “Searching for low-bit weights in quantized neural networks,” Advances in neural information processing systems, vol. 33, pp. 4091-4102, 2020. [5]A. Amirany, M. Meghdadi, M. H. Moaiyeri, and K. Jafari, “Stochastic Spintronic Neuron with Application to Image Binarization,” presented at the 2021 26th International Computer Conference, Computer Society of Iran (CSICC), 2021.

[6]P. Yin, C. Wang, H. Waris, W. Liu, Y. Han, and F. Lombardi, “Design and Analysis of Energy-Efficient Dynamic Range Approximate Logarithmic Multipliers for Machine Learning,” IEEE Transactions on Sustainable Computing, vol. 6, no. 4, pp. 612-625, 2021, doi: 10.1109/tsusc.2020.3004980. [7] M. Natsui, T. Chiba, and T. Hanyu, “Design of MTJ-Based nonvolatile logic gates for quantized neural networks,” Microelectronics Journal, vol. 82, pp. 13-21, 2018, doi: 10.1016/j.mejo.2018.10.005. [8]F. Frustaci, D. Blaauw, D. Sylvester, and M. Alioto, “Approximate SRAMs With Dynamic Energy-Quality Management,” IEEE Transactions on Very Large Scale Integration (VLSI) Systems, vol. 24, no. 6, pp. 2128-2141, 2016, doi: 10.1109/tvlsi.2015.2503733.

[9]A. Raha, S. Sutar, H. Jayakumar, and V. Raghunathan, “Quality Configurable Approximate DRAM,” IEEE Transactions on Computers, vol. 66, no. 7, pp. 1172-1187, 2017, doi: 10.1109/tc.2016.2640296. [10] A. Amirany, K. Jafari, and M. H. Moaiyeri, “High-Performance and Soft Error Immune Spintronic Retention Latch for Highly Reliable Processors,” presented at the Electrical Engineering (ICEE), Iranian Conference on, 2020. [11] A. Amirany, K. Jafari, and M. H. Moaiyeri, “A Task-Schedulable Nonvolatile Spintronic Field-Programmable Gate Array,” IEEE Magnetics Letters, vol. 12, pp. 1-4, 2021, doi: 10.1109/lmag.2021.3092995.

[12] J. Grollier, D. Querlioz, K. Y. Camsari, K. Everschor-Sitte, S. Fukami, and M. D. Stiles, “Neuromorphic spintronics,” Nature Electronics, 2020, doi: 10.1038/s41928-019-0360-9.

[13] Y. Wang, Y. Zhang, E. Y. Deng, J. O. Klein, L. A. B. Naviner, and W. S. Zhao, “Compact model of magnetic tunnel junction with stochastic spin transfer torque switching for reliability analyses,” Microelectronics Reliability, vol. 54, no. 9-10, pp. 1774-1778, 2014, doi: 10.1016/j.microrel.2014.07.019. [14]Y. Qu, J. Han, B. F. Cockburn, W. Pedrycz, Y. Zhang, and W. Zhao, “A true random number generator based on parallel STT-MTJs,” presented at the Design, Automation & Test in Europe Conference & Exhibition (DATE), 2017, 2017. [15] F. Khodayari, A. Amirany, M. H. Moaiyeri, and K. Jafari, “A Variation-Aware Ternary True Random Number Generator Using Magnetic Tunnel Junction at Subcritical Current Regime,” Ieee Transactions on Magnetics, vol. 59, no. 3, pp. 1-1, March 2023, doi: 10.1109/Tmag.2022.3233891.

[16]F. Khodayari, A. Amirany, K. Jafari, and M. H. Moaiyeri, “Low-Cost and Variation-Aware Spintronic Ternary Random Number Generator,” Circuits, Systems, and Signal Processing, 2023, doi: 10.1007/s00034-023-02509-w. [17] S. Mehri, A. Amirany, M. H. Moaiyeri, and K. Jafari, “Theoretical Circuit Design of an Efficient Spintronic Random Number Generator with an Internal Post-Processing Unit,” IEEE Magnetics Letters, pp. 1-5, 2022, doi: 10.1109/lmag.2022.3200326. [18] N. Sayed, R. Bishnoi, and M. B. Tahoori, “Approximate Spintronic Memories,” ACM Journal on Emerging Technologies in Computing Systems, vol. 16, no. 4, pp. 1-22, 2020, doi: 10.1145/3404980. [19]A. Ranjan, S. Venkataramani, X. Fong, K. Roy, and A. Raghunathan, “Approximate storage for energy efficient spintronic memories,” presented at the Proceedings of the 52nd Annual Design Automation Conference, 2015.

[20]I. Hubara, M. Courbariaux, D. Soudry, R. El-Yaniv, and Y. Bengio, “Quantized neural networks: Training neural networks with low precision weights and activations,” The Journal of Machine Learning Research, vol. 18, no. 1, pp. 6869-6898, 2017. [21] Z. Weisheng, S. Chaudhuri, C. Accoto, J. O. Klein, C. Chappert, and P. Mazoyer, “Cross-Point Architecture for Spin-Transfer Torque Magnetic Random Access Memory,” IEEE Transactions on Nanotechnology, vol. 11, no. 5, pp. 907-917, 2012, doi: 10.1109/tnano.2012.2206051. [22] H. Jiang, C. Liu, N. Maheshwari, F. Lombardi, and J. Han, “A comparative evaluation of approximate multipliers,” in 2016 IEEE/ACM International Symposium on Nanoscale Architectures (NANOARCH), 2016: IEEE, pp. 191-196, doi: 10.1145/2950067.2950068. [23] E. Zacharelos, I. Nunziata, G. Saggese, A. G. M. Strollo, and E. Napoli, “Approximate Recursive Multipliers Using Low Power Building Blocks,” IEEE Transactions on Emerging Topics in Computing, vol. 10, no. 3, pp. 1315-1330, 2022, doi: 10.1109/tetc.2022.3186240. [24] Y. LeCun, “LeNet-5, convolutional neural networks,” URL: http://yann.lecun.com/exdb/lenet, vol. 20, no. 5, p. 14, 2015.

The foregoing description and drawings should be considered as illustrative only of the principles of the disclosure, which may be configured in a variety of shapes and sizes and is not intended to be limited by the embodiment herein described. Numerous applications of the disclosure will readily occur to those skilled in the art. Therefore, it is not desired to limit the disclosure to the specific examples disclosed or the exact construction and operation shown and described. Rather, all suitable modifications and equivalents may be resorted to, falling within the scope of the disclosure.

1. A spintronic adaptive approximate memory (SAAM) comprising:
a magnetic tunnel junction (MTJ) having a critical current switching level; and
a write circuit having a write current adaptability to provide a variable write current to selectively provide deterministic or probabilistic switching of said MTJ.

2. The SAAM of claim 1, further comprising a plurality of MTJs each storing a single bit.

3. The SAAM of claim 1, wherein the write current varies the write current.

4. The SAAM of claim 1, said MTJ having an adjustable switching current level configured to provide adjustable approximation in a critical current regime.

5. The SAAM of claim 1, said MTJ having an input with an input value and lower significance bits, and adaptive approximation applied to the lower significance bits based on the input value.

6. The SAAM of claim 1, said MTJ having adaptive approximation based on quality of the application execution feedback.

7. The SAAM of claim 1, further comprising a circuit having one or more transistors, said one or more transistors having a size that provides an MTJ switching current below a critical current for said one or more transistors.

8. The SAAM of claim 7, wherein said one or more transistors are small but can be integrated to act as bigger transistors.

9. The SAAM of claim 7, wherein the small transistors are adaptively integrated at run time.

10. The SAAM of claim 1, further comprising smaller transistors and larger transistors, wherein said MTJ having bit-wise approximation performed at a transistor level using the smaller transistors.

11. The SAAM of claim 1, wherein MTJ switching current below a critical current reduces probability of MTJ switching.

12. The SAAM of claim 1, where approximation is applied only to lower bits in any approximate memories besides spintronic.

13. The SAAM of claim 1, further comprising an input-aware write circuit to use appropriate level approximation based on the input value or quality of the application execution feedback.

14. The SAAM of claim 1, further comprising a smart write circuit that compares input data with stored data to avoid writing duplicate using a comparator circuit to compare the input data against the data already saved in the cell.

15. The SAAM of claim 14, wherein said smart write circuit can assist any other type of memories besides spintronic where write operations are energy inefficient, by avoiding the writing of duplicate values.

16. The SAAM of claim 1, said SAAM having a write operation as a part of the precharge phase, and an evaluation phase having a read operation.

17. A spintronic adaptive approximate memory (SAAM) comprising:
a magnetic tunnel junction (MTJ) having critical current switching level at which the MTJ switches between a low-resistance state and a high-resistance state, wherein a sub-critical current level below the critical current switching level has a lower probability of switching the MTJ between the low-resistance state and the high-resistance state; and
a write circuit configured to provide a write circuit output current that is at the sub-critical current level to provide adjustable approximation based on the lower probability of switching.

18. The SAAM of claim 17, wherein said write circuit output current is adjustable between a first write circuit output current and a second write circuit output current different than the first write circuit output current.

19. The SAAM of claim 18, wherein said write circuit comprises a first transistor connected in parallel to a second transistor, wherein the first or second transistor is used to provide the first write circuit output current, and the first and second transistors are used to provide the second write circuit output current.

20. The SAAM of claim 17, said MTJ having an input with an input value and lower significance bits, wherein the adjustable approximation is applied to the lower significance bits based on the input value.
